(19) United States
(12) Patent Application Publication
(10) Pub. No.: US 2023/0337487 A1
(43) Pub. Date: Oct. 19, 2023

(54) DISPLAY APPARATUS

(71) Applicant: Samsung Display Co., Ltd., Yongin-si (KR)

(72) Inventors: Kiho Bang, Yongin-si (KR); Seunghwan Cho, Yongin-si (KR); Wonsuk Choi, Yongin-si (KR)

(73) Assignee: Samsung Display Co., Ltd., Yongin-si (KR)

(21) Appl. No.: 18/110,452

(22) Filed: Feb. 16, 2023

(30) Foreign Application Priority Data
Apr. 14, 2022 (KR) 10-2022-0046498

(51) Int. Cl. H10K 59/131; H10K 59/40; H10K 59/80; G06F 3/041

(52) U.S. Cl. CPC H10K 59/131; H10K 59/40; H10K 59/873; G06F 3/0412; G09G 2300/0842; G09G 3/3233

(57) ABSTRACT

A display apparatus includes a display area in which a display element is arranged and a peripheral area adjacent to the display area, a dam part disposed on a substrate in the peripheral area to surround the display area, an encapsulation layer disposed on the substrate in the display area and the peripheral area to encapsulate the display element, an organic insulating layer disposed on the encapsulation layer and extending from the display area to the peripheral area to cover the dam part, and a metal pattern disposed on the organic insulating layer and overlapping the dam part in a plan view.

### CROSS-REFERENCE TO RELATED APPLICATION

This application claims priority to and benefits of Korean Patent Application No. 10-2022-0046498 under 35 U.S.C. § 119, filed on Apr. 14, 2022, in the Korean Intellectual Property Office (KIPO), the entire contents of which are incorporated by herein reference.

### BACKGROUND

### 1. Technical Field

One or more embodiments relate to a display apparatus, and more particularly, to a display apparatus including an extended display area.

### 2. Description of the Related Art

Generally, in a display apparatus such as an organic light emitting display apparatus, thin film transistors are arranged in a display area to control the luminance of a light emitting diode or the like. The thin film transistors are arranged to control to emit light with a certain color from the light emitting diode by using the received data signal, driving voltage, and common voltage.

A data driving circuit, a driving voltage supply line, a common voltage supply line, and the like are located in a peripheral area outside the display area to provide the data signal, the driving voltage, the common voltage, and the like.

As the proportion of a display area capable of providing an image in a display apparatus increases, a peripheral area as a dead space in which light emitting diodes are not arranged is reduced. Thus, there is a problem that the space in which components arranged in the peripheral area are to be located decreases.

### SUMMARY

In order to solve various problems including the abovementioned problems, one or more embodiments include a display apparatus including an extended display area because the area of a dead space is reduced. However, these problems are merely examples and the scope of the disclosure is not limited thereto.

Additional aspects will be set forth in part in the description which follows and, in part, will be apparent from the description, or may be learned by practice of the presented embodiments of the disclosure.

According to one or more embodiments, a display apparatus includes a display area in which a display element is arranged and a peripheral area adjacent to the display area, a dam part disposed on a substrate in the peripheral area to surround the display area, an encapsulation layer disposed on the substrate in the display area and the peripheral area to encapsulate the display element, an organic insulating layer disposed on the encapsulation layer and extending from the display area to the peripheral area to cover the dam part, and a metal pattern disposed on the organic insulating layer and overlapping the dam part in a plan view.

In an embodiment, the dam part may include a first dam and a second dam spaced apart from the first dam in a direction of the display area, and the organic insulating layer may fill at least a portion of a valley area between the first dam and the second dam.

In an embodiment, the metal pattern may overlap the first dam or the valley area between the first dam and the second dam in a plan view.

In an embodiment, the dam part may include at least one subdam spaced apart from the second dam in a direction, the encapsulation layer may include at least one inorganic encapsulation layer and at least one organic encapsulation layer, the at least one organic encapsulation layer may extend from the display area to the second dam, and the metal pattern may overlap the at least one organic encapsulation layer in a plan view.

In an embodiment, a thickness of the organic insulating layer in the display area may be about 0.7 μm or more, and a thickness of the organic insulating layer in the valley area may be about 1.4 μm or more.

In an embodiment, the display apparatus may further include at least one inorganic insulating layer disposed on the substrate in the display area and the peripheral area, and an outer dam disposed on the substrate in the peripheral area and covering an end of the at least one inorganic insulating layer.

In an embodiment, the at least one inorganic insulating layer may include a hole or a groove overlapping the outer dam in a plan view.

In an embodiment, the display apparatus may further include a common voltage supply line disposed on the substrate in the peripheral area, wherein the metal pattern and the common voltage supply line may be spaced apart from each other in a plan view.

In an embodiment, the common voltage supply line may include a plurality of conductive lines disposed on different layers.

In an embodiment, the display apparatus may further include a pixel circuit arranged in the display area and including a thin film transistor and a storage capacitor, wherein at least one of the plurality of conductive lines and a source electrode or a drain electrode of the thin film transistor may include a same material.

In an embodiment, the display apparatus may further include a pixel circuit arranged in the display area and including a thin film transistor and a storage capacitor, and a connection electrode electrically connecting a source electrode or a drain electrode of the thin film transistor to a pixel electrode of the display element, wherein at least one of the plurality of conductive lines and the connection electrode may include a same material.

In an embodiment, the common voltage supply line may include an opening portion, and the metal pattern may be located inside the opening portion.

In an embodiment, the opening portion may include a plurality of opening portions.

In an embodiment, the opening portion may contact an outer boundary of the common voltage supply line.

In an embodiment, a width of the opening portion in a first direction may be greater than a width of the metal pattern in the first direction.

In an embodiment, the dam part may include a first dam, and a second dam spaced apart from the first dam in a direction, and the first dam may cover an outer boundary of the common voltage supply line.

In an embodiment, the common voltage supply line may include an opening portion overlapping a valley area between the first dam and the second dam in a plan view, and the metal pattern may be located inside the opening portion.

In an embodiment, the display apparatus may further include a first touch conductive layer disposed on the encapsulation layer, and a second touch conductive layer disposed on the first touch conductive layer, wherein the organic insulating layer may be located between the first touch conductive layer and the second touch conductive layer.

In an embodiment, the metal pattern and the second touch conductive layer may include a same material.

In an embodiment, the second touch conductive layer may include an input signal line overlapping the peripheral area in a plan view, and the metal pattern may be spaced apart from the input signal line.

Other aspects, features, and advantages other than those described above will become apparent from the accompanying drawings, the appended claims, and the detailed description of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a plan view schematically illustrating a portion of a display apparatus according to an embodiment;

FIG. 2 is a cross-sectional view schematically illustrating a portion of a display apparatus according to an embodiment;

FIGS. 3 and 4 are schematic diagrams of equivalent circuits of a pixel that may be included in a display apparatus according to an embodiment;

FIG. 5 is a cross-sectional view schematically illustrating a portion of a display apparatus according to an embodiment;

FIG. 6 is a plan view schematically illustrating a portion of a display apparatus according to an embodiment;

FIGS. 7 and 8 are schematic enlarged plan views of region A of the display apparatus of FIG. 1;

FIG. 9 is a schematic cross-sectional view of region A taken along line B-B′ of FIG. 7, and FIG. 10 is a schematic cross-sectional view of region A taken along line C-C′ of FIG. 7;

FIG. 11 is a schematic enlarged cross-sectional view of region D of FIG. 10;

FIG. 12 is a plan view schematically illustrating a modification of FIG. 8;

FIG. 13 is a schematic cross-sectional view of the modification taken along line E-E′ of FIG. 12; and

FIG. 14 is a graph illustrating the step height of a first insulating layer and the step height of an organic insulating layer in an area overlapping the upper surface of a first dam and in a valley area between the first dam and a second dam.

### DETAILED DESCRIPTION OF THE EMBODIMENTS

Reference will now be made in detail to embodiments, examples of which are illustrated in the accompanying drawings, wherein like reference numerals refer to like elements throughout. In this regard, the embodiments may have different forms and should not be construed as being limited to the descriptions set forth herein. Accordingly, the embodiments are merely described below, by referring to the figures, to explain aspects of the description.

The disclosure may include various embodiments and modifications, and certain embodiments thereof are illustrated in the drawings and will be described herein in detail. The effects and features of the disclosure and the accomplishing methods thereof will become apparent from the embodiments described below in detail with reference to the accompanying drawings. However, the disclosure is not limited to the embodiments described below and may be embodied in various modes.

Hereinafter, embodiments will be described in detail with reference to the accompanying drawings, and in the following description, and redundant descriptions thereof will be omitted for conciseness.

It will be understood that although terms such as “first” and “second” may be used herein to describe various components, these components should not be limited by these terms and these terms are only used to distinguish one component from another component.

As used herein, the singular forms “a,” “an,” and “the” are intended to include the plural forms as well, unless the context clearly indicates otherwise.

Also, it will be understood that the terms “comprise,” “include,” and “have” used herein specify the presence of stated features or components, but do not preclude the presence or addition of one or more other features or components.

It will be understood that when a layer, region, or component is referred to as being “on” another layer, region, or component, it may be “directly on” the other layer, region, or component or may be “indirectly on” the other layer, region, or component with one or more intervening layers, regions, or components therebetween.

It will be understood that when a layer, region, or component is referred to as being “connected to” another layer, region, or component, it may be “directly connected to” the other layer, region, or component or may be “indirectly connected to” the other layer, region, or component with one or more intervening layers, regions, or components therebetween. For example, it will be understood that when a layer, region, or component is referred to as being “electrically connected to” another layer, region, or component, it may be “directly electrically connected to” the other layer, region, or component and/or may be “indirectly electrically connected to” the other layer, region, or component with one or more intervening layers, regions, or components therebetween.

The term “and/or” includes all combinations of one or more of which associated configurations may define. For example, “A and/or B” may be understood to mean “A, B, or A and B.”

For the purposes of this disclosure, the phrase “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z.

As used herein, the x-axis, the y-axis, and the z-axis are not limited to three axes of the rectangular coordinate system, and may be interpreted in a broader sense. For example, the x axis, the y axis, and the z axis may be perpendicular to one another or may represent different directions that are not perpendicular to one another.

When a certain embodiment may be implemented differently, a particular process order may be performed differently from the described order. For example, two consecutively described processes may be performed substantially at the same time or may be performed in an order opposite to the described order.

Sizes of elements in the drawings may be exaggerated for convenience of description. In other words, because the sizes and thicknesses of elements in the drawings are arbitrarily illustrated for convenience of description, the disclosure is not limited thereto.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined or implied herein, all terms (including technical and scientific terms) used herein have the same meaning as commonly understood by those skilled in the art to which this disclosure pertains. It will be further understood that terms, such as those defined in commonly used dictionaries, should be interpreted as having a meaning that is consistent with their meaning in the context of the relevant art and the disclosure, and should not be interpreted in an ideal or excessively formal sense unless clearly so defined herein.

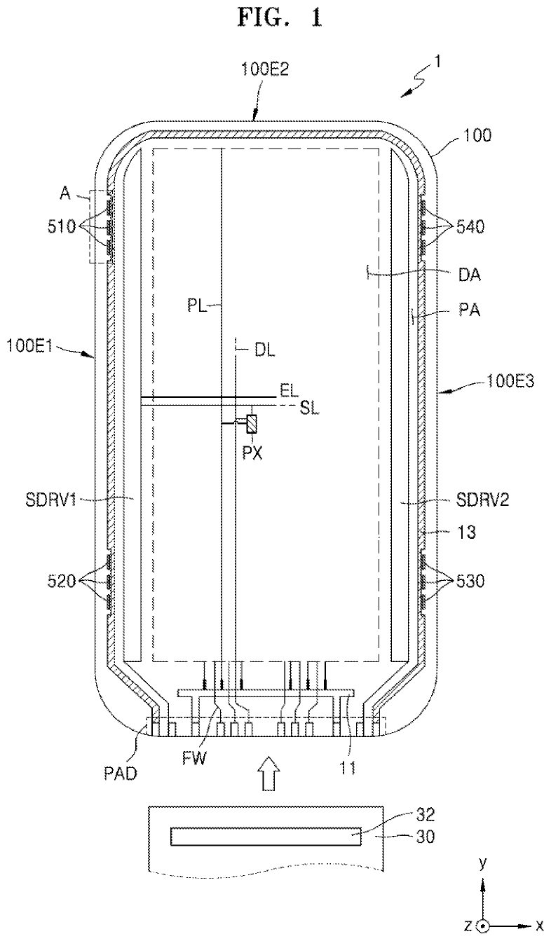

FIG. 1 is a plan view schematically illustrating a portion of a display apparatus according to an embodiment.

Referring to FIG. 1, a display apparatus 1 may include a display panel. The display apparatus 1 may be any type as long as it includes a display panel described below. For example, the display apparatus 1 may include various products such as smartphones, tablet personal computers (PCs), laptops, televisions, or billboards.

The display apparatus 1 may include a substrate 100 including a display area DA and a peripheral area PA outside (or adjacent to) the display area DA. The display area DA and the peripheral area PA may be defined in the display apparatus 1. Herein, that a component is located in the display area DA may mean that the component is disposed on the display area DA of the substrate 100 or may be disposed overlapping the display area DA of the substrate 100. Likewise, that a component is located in the peripheral area PA may mean that the component is disposed on the peripheral area PA of the substrate 100 or may be disposed overlapping the peripheral area PA of the substrate 100.

The display area DA may be an area for displaying an image, and pixels PX may be arranged in the display area DA. In a view in a direction substantially perpendicular to the substrate 100, the display area DA may have various shapes such as a circular shape, an elliptical shape, a polygonal shape, and a particular figure shape. FIG. 1 illustrates that the display area DA has a substantially rectangular shape; however, in another embodiment, the display area DA may have a rectangular shape with rounded corners.

Each of the pixels PX may include a display element such as an organic light emitting diode (OLED). Each pixel PX may emit, for example, red, green, blue, or white light.

The peripheral area PA may be an area that is arranged outside the display area DA and displays no image. The peripheral area PA may entirely surround the display area DA. The peripheral area PA may include outer circuits for driving the pixels PX. For example, a first scan driving circuit SDRV1, a second scan driving circuit SDRV2, a terminal part PAD, a driving voltage supply line 11, and a common voltage supply line 13 may be arranged in the peripheral area PA.

The first scan driving circuit SDRV1 may apply a scan signal to each of the pixel circuits driving the pixels PX, through a scan line SL. The second scan driving circuit SDRV2 may be located on the opposite side of the first scan driving circuit SDRV1 with respect to the display area DA and may be substantially parallel to the first scan driving circuit SDRV1. Some of the pixel circuits of the pixels PX arranged in the display area DA may be electrically connected to the first scan driving circuit SDRV1, and the others may be electrically connected to the second scan driving circuit SDRV2.

The terminal part PAD may be arranged at a side of the substrate 100. The terminal part PAD may be exposed by not being covered (or overlapped) by an insulating layer, to be electrically connected to a display circuit board 30. A display driver 32 may be arranged at the display circuit board 30. The display driver 32 may generate a control signal transmitted to the first scan driving circuit SDRV1 and the second scan driving circuit SDRV2. The display driver 32 may supply a driving voltage ELVDD to the driving voltage supply line 11 and may supply a common voltage ELVSS to the common voltage supply line 13. The driving voltage ELVDD may be applied to the pixel circuit of the pixels PX through a driving voltage line PL electrically connected to the driving voltage supply line 11, and the common voltage ELVSS may be applied to the opposite electrode of the display element electrically connected to the common voltage supply line 13. The display driver 32 may generate a data signal, and the generated data signal may be transmitted to the pixel circuit of the pixels PX through a fanout line FW and a data line DL electrically connected to the fanout line FW.

The driving voltage supply line 11 may be provided extending in a first direction (e.g., the x direction) on the lower side of the display area DA. The common voltage supply line 13 may have a shape in which one side is open in a loop shape, to partially surround the display area DA.

The display apparatus 1 may include metal patterns 510, 520, 530, and 540 arranged outside the display area DA. The metal patterns 510, 520, 530, and 540 may be island patterns and the metal patterns 510, 520, 530, and 540 may be separated from or electrically insulated from other components.

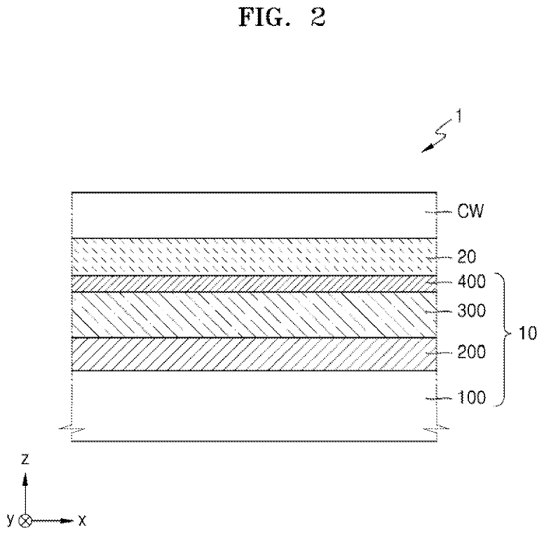

In a process of joining a display panel 10 (see FIG. 2) and a cover window CW (or a functional module 20) (see FIG. 2) together, the metal patterns 510, 520, 530, and 540 may be used as an identification mark for detecting the position of the display panel 10 (see FIG. 2) or aligning the display panel 10 (see FIG. 2).

The metal patterns 510, 520, 530, and 540 may be arranged apart (or spaced apart) from the common voltage supply line 13. For example, in a view in a direction substantially perpendicular to the substrate 100, the metal patterns 510, 520, 530, and 540 and the common voltage supply line 13 may not overlap each other. For example, an opening portion may be formed by removing a portion of the common voltage supply line 13, and the metal patterns 510, 520, 530, and 540 may be arranged in the opening portion. Thus, in case that light is irradiated from the rear surface of the display panel, the shadow of the metal patterns 510, 520, 530, and 540 may be prevented from not being identified due to the shadow of the common voltage supply line 13.

In an embodiment, a first metal pattern 510 and a fourth metal pattern 540 may be arranged to face each other on the upper side of the peripheral area PA with the display area DA therebetween. Likewise, a second metal pattern 520 and a third metal pattern 530 may be arranged to face each other on the lower side of the peripheral area PA with the display area DA therebetween. In this regard, FIG. 1 illustrates that the metal patterns 510, 520, 530, and 540 are arranged adjacent to a first boundary 100E1 and a third boundary 100E3 of the substrate 100; however, the disclosure is not limited thereto. For example, the metal patterns 510, 520, 530, and 540 may further include metal patterns arranged adjacent to the first boundary 100E1, a second boundary 100E2, and the third boundary 100E3 of the substrate 100 along the common voltage supply line 13. As another example, some of the metal patterns 510, 520, 530, and 540 may be omitted.

FIG. 2 is a cross-sectional view schematically illustrating a portion of the display apparatus illustrated in FIG. 1.

Referring to FIG. 2, the display apparatus 1 may include a display panel 10, a functional module 20, and a cover window CW.

The display panel 10 may include a substrate 100, a display element layer 200, an encapsulation layer 300, and an input sensing layer 400.

The substrate 100 may include an insulating material such as glass, quartz, or polymer resin. The substrate 100 may include a rigid substrate or a flexible substrate capable of bending, folding, rolling, or the like. For example, the substrate 100 may include a polymer resin such as polyethersulfone, polyacrylate, polyetherimide, polyethylene naphthalate, polyethylene terephthalate, polyphenylene sulfide, polyarylate, polyimide, polycarbonate, or cellulose acetate propionate. The substrate 100 may have a multilayer structure including an inorganic layer (not illustrated) and a layer including the above polymer resin. For example, the substrate 100 may include two layers including the above polymer resin and an inorganic barrier layer arranged therebetween.

The display element layer 200 may be disposed on the substrate 100. The display element layer 200 may include pixels and may be a layer that displays an image. The display element layer 200 may include display elements and pixel circuits electrically connected to the display elements. The display element layer 200 may include scan lines, data lines, and/or power lines electrically connected to the pixel circuit, a scan driver for applying scan signals to the scan lines, and/or fanout lines for connecting the data lines and a display driver.

The encapsulation layer 300 for encapsulating the display element may be disposed on the display element layer 200. The encapsulation layer 300 may include at least one organic encapsulation layer to provide a more planarized base surface. Thus, a defect rate may be reduced even in case that the input sensing layer 400 described below is formed by a continuous process.

The input sensing layer 400 may be directly disposed on the encapsulation layer 300. The input sensing layer 400 may include touch electrodes and/or an input signal line electrically connected to the touch electrodes and may be a layer for sensing whether a user touches. The input sensing layer 400 may sense whether a user touches, for example, by a capacitive method. In the disclosure, an operation method of the input sensing layer 400 is not particularly limited, and in an embodiment, the input sensing layer 400 may sense an external input by an electromagnetic induction method or a pressure sensing method.

The “layers” constituting the display panel 10 may be formed through a continuous process with other components. For example, the substrate 100 of the display panel 10 may function as a base layer providing a base surface, and the display element layer 200, the encapsulation layer 300, and the input sensing layer 400 may be disposed on a base surface provided by another component.

The functional module 20 may be disposed over the display panel 10. The functional module 20 may include at least one functional layer. The functional layer may be a layer that performs a color filtering function, a color conversion function, a polarization function, or the like. The functional layer may be a sheet layer including a sheet, a film layer including a film, a thin film layer, a coating layer, a panel, a plate, or the like. A functional layer may include a single layer or may include stacked thin films or coating layers. For example, the functional layer may be a color filter, an optical film, or the like. The functional module 20 may be omitted.

The cover window CW may be disposed over the functional module 20. As another example, the functional module 20 may be omitted, and the cover window CW may be disposed over the display panel 10. The cover window CW may function to protect the upper surface of the display panel 10.

The functional module 20 or the cover window CW may be coupled to (or connected to) the display panel 10 by using an optically clear adhesive (OCA) or an optically clear resin (OCR).

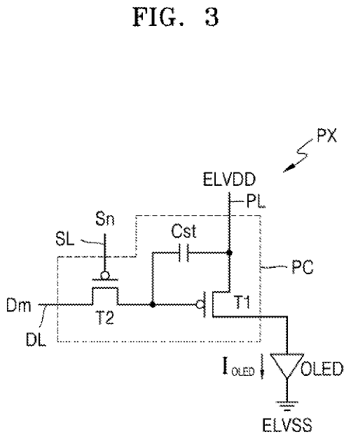

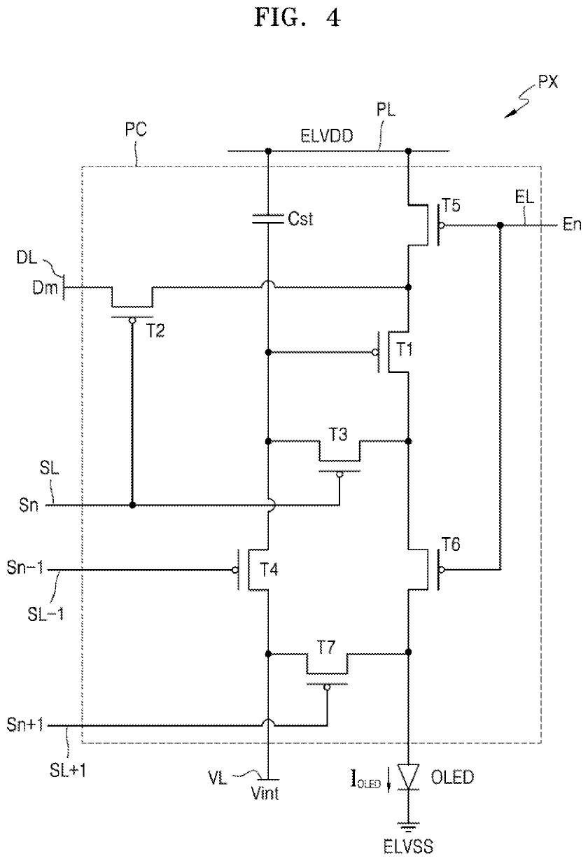

FIGS. 3 and 4 are schematic diagrams of equivalent circuits of a pixel that may be included in a display apparatus according to an embodiment.

Referring to FIG. 3, a pixel circuit PC may be electrically connected to a display element OLED to implement light emission of pixels PX. The pixel circuit PC may include a driving thin film transistor T1, a switching thin film transistor T2, and a storage capacitor Cst. In an embodiment, the display element OLED may be a light emitting element such as an organic light emitting element or an inorganic light emitting element but is not limited thereto. The switching thin film transistor T2 may be electrically connected to a scan line SL and a data line DL and may be configured to transmit a data signal Dm input through the data line DL to the driving thin film transistor T1 according to a scan signal Sn input through the scan line SL.

The storage capacitor Cst may be electrically connected to the switching thin film transistor T2 and a driving voltage line PL and may store a voltage corresponding to the difference between a voltage received from the switching thin film transistor T2 and a driving voltage ELVDD supplied to the driving voltage line PL.

The driving thin film transistor T1 may be electrically connected to the driving voltage line PL and the storage capacitor Cst and may control a driving current IDLED flowing from the driving voltage line PL to the display element OLED in response to a voltage value stored in the storage capacitor Cst.

An organic light emitting diode OLED may include a pixel electrode and an opposite electrode, wherein the pixel electrode may be connected to the driving transistor T1, and the opposite electrode may receive a common voltage ELVSS. The display element OLED may emit light with a certain brightness according to the driving current IDLED.

Referring to FIG. 4, a pixel circuit PC may include a driving thin film transistor T1, a switching thin film transistor T2, a compensation thin film transistor T3, a first initialization thin film transistor T4, an operation control thin film transistor T5, an emission control thin film transistor T6, and a second initialization thin film transistor T7.

Although FIG. 4 illustrates that each pixel circuit PC includes signal lines SL, SL−1, SL+1, EL, and DL, an initialization voltage line VL, and a driving voltage line PL, the disclosure is not limited thereto. In other embodiments, at least one of the signal lines SL, SL−1, SL+1, EL, and DL and/or the initialization voltage line VL may be shared by adjacent pixel circuits.

The drain electrode of the driving thin film transistor T1 may be electrically connected to the display element OLED via the emission control thin film transistor T6. The driving thin film transistor T1 may receive a data signal Dm according to a switching operation of the switching thin film transistor T2 and supply a driving current IDLED to the display element OLED.

The gate electrode of the switching thin film transistor T2 may be electrically connected to the scan line SL, and the source electrode thereof may be electrically connected to the data line DL. The drain electrode of the switching thin film transistor T2 may be electrically connected to the driving voltage line PL via the operation control thin film transistor T5 while being electrically connected to the source electrode of the driving thin film transistor T1.

The switching thin film transistor T2 may be turned on according to a scan signal Sn received through the scan line SL, to perform a switching operation of transmitting the data signal Dm transmitted to the data line DL to the source electrode of the driving thin film transistor T1.

The gate electrode of the compensation thin film transistor T3 may be electrically connected to the scan line SL. The source electrode of the compensation thin film transistor T3 may be electrically connected to the pixel electrode of the display element OLED via the emission control thin film transistor T6 while being electrically connected to the drain electrode of the driving thin film transistor T1. The drain electrode of the compensation thin film transistor T3 may be electrically connected to at least one electrode of the storage capacitor Cst, the source electrode of the first initialization thin film transistor T4, and the gate electrode of the driving thin film transistor T1. The compensation thin film transistor T3 may be turned on according to the scan signal Sn received through the scan line SL, to connect the gate electrode and the drain electrode of the driving thin film transistor T1 to each other to diode-connect the driving thin film transistor T1.

The gate electrode of the first initialization thin film transistor T4 may be electrically connected to the previous scan line SL−1. The drain electrode of the first initialization thin film transistor T4 may be electrically connected to the initialization voltage line VL. The source electrode of the first initialization thin film transistor T4 may be electrically connected to at least one electrode of the storage capacitor Cst, the drain electrode of the compensation thin film transistor T3, and the gate electrode of the driving thin film transistor T1. The first initialization thin film transistor T4 may be turned on according to a previous scan signal Sn−1 received through the previous scan line SL−1, to perform an initialization operation of initializing the voltage of the gate electrode of the driving thin film transistor T1 by transmitting an initialization voltage Vint to the gate electrode of the driving thin film transistor T1.

The gate electrode of the operation control thin film transistor T5 may be electrically connected to an emission control line EL. The source electrode of the operation control thin film transistor T5 may be electrically connected to the driving voltage line PL. The drain electrode of the operation control thin film transistor T5 may be electrically connected to the source electrode of the driving thin film transistor T1 and the drain electrode of the switching thin film transistor T2.

The gate electrode of the emission control thin film transistor T6 may be electrically connected to the emission control line EL. The source electrode of the emission control thin film transistor T6 may be electrically connected to the drain electrode of the driving thin film transistor T1 and the source electrode of the compensation thin film transistor T3. The drain electrode of the emission control thin film transistor T6 may be electrically connected to the pixel electrode of the display element OLED. The operation control thin film transistor T5 and the emission control thin film transistor T6 may be simultaneously turned on according to an emission control signal En received through the emission control line EL, such that the driving voltage ELVDD may be transmitted to the display element OLED and the driving current IDLED may flow through the display element OLED.

The gate electrode of the second initialization thin film transistor T7 may be electrically connected to the next scan line SL+1. The source electrode of the second initialization thin film transistor T7 may be electrically connected to the pixel electrode of the display element OLED. The drain electrode of the second initialization thin film transistor T7 may be electrically connected to the initialization voltage line VL. The second initialization thin film transistor T7 may initialize the pixel electrode of the display element OLED by being turned on according to a next scan signal Sn+1 received through the next scan line SL+1.

Although FIG. 4 illustrates a case where the first initialization thin film transistor T4 and the second initialization thin film transistor T7 are respectively electrically connected to the previous scan line SL−1 and the next scan signal SL+1, the disclosure is not limited thereto. In other embodiments, both the first initialization thin film transistor T4 and the second initialization thin film transistor T7 may be electrically connected to the previous scan line SL−1 to be driven according to the previous scan signal Sn−1.

Another electrode of the storage capacitor Cst may be electrically connected to the driving voltage line PL. At least one electrode of the storage capacitor Cst may be electrically connected to the gate electrode of the driving thin film transistor T1, the drain electrode of the compensation thin film transistor T3, and the source electrode of the first initialization thin film transistor T4.

The opposite electrode (e.g., cathode) of the display element OLED may be provided with a common voltage ELVSS. The display element OLED may emit light by receiving a driving current IDLED from the driving thin film transistor T1.

The pixel circuit PC is not limited to the number and circuit design of the thin film transistors and storage capacitor described with reference to FIGS. 3 and 4, and the number and circuit design thereof may be variously modified.

In some embodiments, some of thin film transistors T1 to T7 may be provided as N-type metal-oxide-semiconductor field-effect transistors (MOSFETs), and the others may be provided as P-type MOSFETs. For example, among the thin film transistors T1 to T7, the driving thin film transistor T1, the switching thin film transistor T2, the operation control thin film transistor T5, and the emission control thin film transistor T6 may be provided as P-type MOSFETs, and the compensation thin film transistor T3 and the first initialization thin film transistor T4 and/or the second initialization thin film transistor T7 may be provided as N-type MOSFETs. As another example, all of the plurality of thin film transistors T1 to T7 may be provided as N-type MOSFETs.

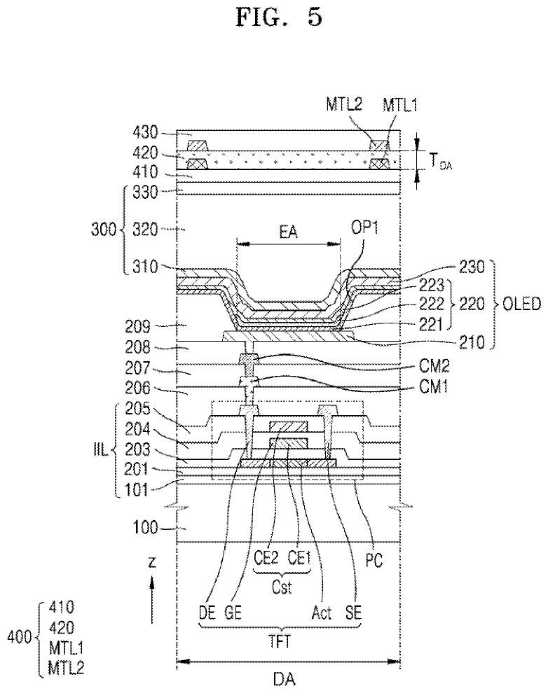

FIG. 5 is a cross-sectional view schematically illustrating a portion of a display apparatus according to an embodiment.

Referring to FIG. 5, a display element OLED and a pixel circuit PC electrically connected to the display element OLED may be disposed on the display area DA of the substrate 100.

As described above, the substrate 100 may include an insulating material such as glass, quartz, or polymer resin. The substrate 100 may include a rigid substrate or a flexible substrate capable of bending, folding, rolling, or the like.

A buffer layer 201 may be located on the substrate 100 to reduce or block the penetration of foreign materials, moisture, or external air from under the substrate 100 and may provide a flat surface on the substrate 100. The buffer layer 201 may include an inorganic material such as oxide or nitride, an organic material, or an organic/inorganic composite and may include a single-layer or multiple-layer structure of an inorganic material and an organic material.

A barrier layer 101 for blocking the penetration of external air may be further included between the substrate 100 and the buffer layer 201. In some embodiments, the buffer layer 201 may include silicon oxide (SiO₂) or silicon nitride (SiNₓ).

The pixel circuit PC including a thin film transistor TFT and a storage capacitor Cst may be disposed on the buffer layer 201.

The thin film transistor TFT may include a semiconductor layer Act, a gate electrode GE, a drain electrode DE, and a source electrode SE.

The semiconductor layer Act may be disposed on the buffer layer 201 and may include polysilicon. In other embodiments, the semiconductor layer Act may include amorphous silicon. In other embodiments, the semiconductor layer Act may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The semiconductor layer Act may include a channel area and a source area and a drain area that are doped with dopants.

A first gate insulating layer 203 may be provided to cover (or overlap, e.g., in a plan view) the semiconductor layer Act. The first gate insulating layer 203 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), and hafnium oxide (HfO₂), or zinc oxide (ZnO₂). The first gate insulating layer 203 may include a single layer or multiple layers including the above inorganic insulating material.

The gate electrode GE may be disposed over the first gate insulating layer 203 to overlap the semiconductor layer Act. The gate electrode GE may include molybdenum (Mo), aluminum (Al), copper (Cu), titanium (Ti), or the like and may include a single layer or multiple layers. For example, the gate electrode GE may include a single layer of Mo.

A second gate insulating layer 204 may be provided to cover the gate electrode GE. The second gate insulating layer 204 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), and hafnium oxide (HfO₂), or zinc oxide (ZnO₂). The second gate insulating layer 204 may include a single layer or multiple layers including the above inorganic insulating material.

A second capacitor plate CE2 of the storage capacitor Cst may be disposed on the second gate insulating layer 204. The second capacitor plate CE2 may overlap the gate electrode GE. The gate electrode GE and the second capacitor plate CE2 overlapping each other with the second gate insulating layer 204 therebetween may constitute the storage capacitors Cst. For example, the gate electrode GE may function as a first capacitor plate CE1 of the storage capacitor Cst.

The second capacitor plate CE2 may include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may include a single layer or multiple layers of the above material.

An interlayer insulating layer 205 may be formed to cover the second capacitor plate CE2. The interlayer insulating layer 205 may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zinc oxide (ZnO₂). The interlayer insulating layer 205 may include a single layer or multiple layers including the above inorganic insulating material.

The buffer layer 201, the first gate insulating layer 203, the second gate insulating layer 204, and the interlayer insulating layer 205 described above may be collectively referred to as an inorganic insulating layer IIL.

The source electrode SE and the drain electrode DE may be disposed on the interlayer insulating layer 205. The source electrode SE and the drain electrode DE may include a conductive material including molybdenum (Mo), aluminum (Al), copper (Cu), titanium (Ti), or the like and may include a single layer or multiple layers including the above material. For example, the source electrode SE and the drain electrode DE may include a multilayer structure of Ti/Al/Ti. In some embodiments, the source electrode SE or the drain electrode DE may be omitted. For example, adjacent thin film transistors TFTs may share a source area or a drain area of the semiconductor layer Act, and the source area or the drain area may function as the source electrode SE or the drain electrode DE.

A first planarization insulating layer 206, a second planarization insulating layer 207, and a third planarization insulating layer 208 may be sequentially arranged to cover the source electrode SE and the drain electrode DE. The third planarization insulating layer 208 may have a flat upper surface such that a pixel electrodes 210 disposed thereover may be formed flat.

The first planarization insulating layer 206, the second planarization insulating layer 207, and the third planarization insulating layer 208 may include an organic material or an inorganic material and may have a single-layer structure or a multilayer structure. The first planarization insulating layer 206, the second planarization insulating layer 207, and the third planarization insulating layer 208 may include a general-purpose polymer such as benzocyclobutene (BCB), polyimide, hexamethyldisiloxane (HMDSO), polymethylmethacrylate (PMMA), or polystyrene (PS), a polymer derivative having a phenolic group, an acrylic polymer, an imide-based polymer, an aryl-ether-based polymer, an amide-based polymer, a fluorine-based polymer, a p-xylene-based polymer, or a vinyl alcohol-based polymer. The first planarization insulating layer 206, the second planarization insulating layer 207, and the third planarization insulating layer 208 may include an inorganic insulating material such as silicon oxide (SiO₂), silicon nitride (SiNₓ), silicon oxynitride (SiON), aluminum oxide (Al₂O₃), titanium oxide (TiO₂), tantalum oxide (Ta₂O₅), and hafnium oxide (HfO₂), or zinc oxide (ZnO₂). In case that the first planarization insulating layer 206, the second planarization insulating layer 207, and the third planarization insulating layer 208 are formed, after a layer is formed, chemical mechanical polishing may be performed on an upper surface of the layer to provide a flat upper surface.

A first connection electrode CM1 may be disposed on the first planarization insulating layer 206. The first planarization insulating layer 206 may include a via hole exposing at least one of the source electrode SE and the drain electrode DE of the thin film transistor TFT, and the first connection electrode CM1 may be electrically connected to the thin film transistor TFT by contacting the source electrode SE or the drain electrode DE through the via hole.

A second connection electrode CM2 may be disposed on the second planarization insulating layer 207. The second planarization insulating layer 207 may include a via hole exposing the first connection electrode CM1, and the second connection electrode CM2 may be electrically connected to the first connection electrode CM1 through the via hole.

The first connection electrode CM1 and the second connection electrode CM2 may include a conductive material including molybdenum (Mo), aluminum (Al), copper (Cu), titanium (Ti), or the like and may include a single layer or multiple layers including the above material.

A pixel electrode 210 may be disposed on the third planarization insulating layer 208. The third planarization insulating layer 208 may include a via hole exposing the second connection electrode CM2, and the pixel electrode 210 may be electrically connected to the thin film transistor TFT by contacting the second connection electrode CM2 through the via hole.

In some embodiments, at least one of the second planarization insulating layer 207 and the second planarization insulating layer 208 may be omitted. For example, the first planarization insulating layer 206 and the second planarization insulating layer 207 may be disposed on the interlayer insulating layer 205, and the pixel electrode 210 may be disposed on the second planarization insulating layer 207. The pixel electrode 210 may be electrically connected to the thin film transistor TFT by contacting the first connection electrode CM1 through the via hole of the second planarization insulating layer 207 exposing the first connection electrode CM1.

The pixel electrode 210 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The pixel electrode 210 may include a reflective layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. For example, the pixel electrode 210 may have a structure including layers formed of ITO, IZO, ZnO, or In₂O₃ over or under the reflective layer described above. The pixel electrode 210 may have a stack structure of ITO/Ag/ITO.

A pixel definition layer 209 may cover an edge of the pixel electrode 210 on the third planarization insulating layer 208 and may include a pixel opening OP1 exposing a central portion of the pixel electrode 210. An emission area of the display element OLED, for example, the size and shape of a pixel, may be defined by the pixel opening OP1.

The pixel definition layer 209 may increase the distance between the edge of the pixel electrode 210 and an opposite electrode 230 over the pixel electrode 210 to prevent an arc or the like from occurring at the edge of the pixel electrode 210. The pixel definition layer 209 may be formed of an organic insulating material such as polyimide, polyamide, acrylic resin, benzocyclobutene, hexamethyldisiloxane (HMDSO), or phenol resin by spin coating or the like.

The pixel definition layer 209 may be formed in black. The pixel definition layer 209 may include a light blocking material and may be provided in black. The light blocking material may include a resin or paste including carbon black, carbon nanotube, or black dye, metal particles (e.g., nickel (Ni), aluminum (Al), molybdenum (Mo), or any alloy thereof), metal oxide particles (e.g., chromium oxide), or metal nitride particles (e.g., chromium nitride). In case that the pixel definition layer 209 includes the light blocking material, the reflection of external light by metal structures disposed under the pixel definition layer 209 may be reduced.

An emission layer 222 formed to correspond to the pixel electrode 210 may be arranged inside the pixel opening OP1 of the pixel definition layer 209. The emission layer 222 may include a high molecular weight material or a low molecular weight material and may emit red, green, blue, or white light.

A first functional layer 221 and a second functional layer 223 may be disposed under and/or over the emission layer 222. In an embodiment, unlike the emission layer 222 being patterned for each pixel, the first functional layer 221 and the second functional layer 223 may be integrally provided over the entire surface of the display area DA.

The first functional layer 221 may include a single layer or multiple layers. For example, in case that the first functional layer 221 is formed of a high molecular weight material, the first functional layer 221 may include a hole transport layer (HTL) having a single-layer structure and may be formed of poly-(3,4)-ethylene-dihydroxy thiophene (PEDOT) or polyaniline (PANI). In case that the first functional layer 221 is formed of a low molecular weight material, the first functional layer 221 may include a hole injection layer (HIL) and an HTL.

The second functional layer 223 may be optionally arranged. For example, in case that the first functional layer 221 and the emission layer 222 are formed of a high molecular weight material, the second functional layer 223 may be formed. The second functional layer 223 may include a single layer or multiple layers. The second functional layer 223 may include an electron transport layer (ETL) and/or an electron injection layer (EIL). In some embodiments, at least one of the hole injection layer (HIL), the hole transport layer (HTL), the electron transport layer (ETL), and the electron injection layer (EIL) may be omitted.

The hole injection layer (HIL) may facilitate hole injection and may include at least one of HATCN and cupper phthalocyanine (CuPc), poly(3,4)-ethylenedioxythiophene (PEDOT), polyaniline (PANI), and N, N-dinaphthyl-N, N′-diphenylbenzidine (NPD); however, the disclosure is not limited thereto.

The hole transport layer (HTL) may include, as a host, a triphenylamine derivative having high hole mobility and excellent stability, such as N, N′-diphenyl-N,N′-bis(3-methylphenyl)-1,1′-bi-phenyl-4,4′-diamine (TPD) or N, N′-di(naphthalen-1-yl)-N,N′-diphenyl-benzidine (NPB).

The electron transport layer (ETL) may facilitate electron transport and may include at least one of tris(8-hydroxyquinolino)aluminum (Alq3), PBD, TAZ, spiro-PBD, BAlq, lithium quinolate (Liq), BMB-3T, PF-6P, TPBI, COT, and SAlq; however, the disclosure is not limited thereto.

The electron injection layer (EIL) may facilitate electron injection and may include Yb, tris(8-hydroxyquinolino)aluminum (Alq3), PBD, TAZ, spiro-PBD, BAlq, or SAlq; however, the disclosure is not limited thereto.

The opposite electrode 230 may include a conductive material having a relatively low work function. For example, the opposite electrode 230 may include a (semi)transparent layer including silver (Ag), magnesium (Mg), aluminum (Al), nickel (Ni), chromium (Cr), lithium (Li), calcium (Ca), or any alloy thereof. As another example, the opposite electrode 230 may further include a layer such as ITO, IZO, ZnO, or In₂O₃ on the (semi)transparent layer including the above material. In an embodiment, the opposite electrode 230 may include silver (Ag) and magnesium (Mg).

A stack structure of the pixel electrode 210, an intermediate layer 220, and the opposite electrode 230 sequentially stacked may form a light emitting diode.

In an embodiment, a capping layer (not illustrated) may be disposed on the display element OLED. The capping layer may improve the light emission efficiency of the display element OLED according to the principle of constructive interference. The capping layer may be an organic capping layer including an organic material, an inorganic capping layer including an inorganic material, or a composite capping layer including an organic material and an inorganic material. For example, the capping layer may include a carbocyclic compound, a heterocyclic compound, an amine group-containing compound, a porphine derivative, a phthalocyanine derivative, a naphthalocyanine derivative, an alkali metal complex, an alkaline earth metal complex, or any combination thereof. The carbocyclic compound, the heterocyclic compound, and the amine group-containing compound may be selectively substituted with a substituent including O, N, S, Se, Si, F, Cl, Br, I, or any combination thereof.

The encapsulation layer 300 may be disposed on the display element OLED. In an embodiment, the encapsulation layer 300 may include at least one inorganic encapsulation layer and at least one organic encapsulation layer. For example, the encapsulation layer 300 may include first and second inorganic encapsulation layers 310 and 330 and an organic encapsulation layer 320 arranged therebetween.

The first and second inorganic encapsulation layers 310 and 330 may each include one or more inorganic insulating materials. The inorganic insulating material may include aluminum oxide (Al₂O₃), titanium oxide (TiO₂), tantalum oxide (Ta₂O₅), hafnium oxide (HfO₂), zinc oxide (ZnO), silicon oxide (SiOₓ), silicon nitride (SiNₓ), and/or silicon oxynitride (SiON). The first and second inorganic encapsulation layers 310 and 330 may be formed through chemical vapor deposition.

The organic encapsulation layer 320 may include polyethylene terephthalate, polyethylene naphthalate, polycarbonate, polyimide, polyethylene sulfonate, polyoxymethylene, polyarylate, hexamethyldisiloxane, acrylic resin (e.g., polymethyl methacrylate or polyacrylic acid), or any combination thereof.

The encapsulation layer 300 may entirely cover the display area DA and may extend to the peripheral area PA to cover at least a portion of the peripheral area PA.

As described above, the encapsulation layer 300 may include the organic encapsulation layer 320 to provide a more planarized base surface. Thus, a defect rate may be reduced even in case that the components of the input sensing layer 400 are formed by a continuous process.

The input sensing layer 400 may have a multilayer structure. The input sensing layer 400 may include a sensing electrode, a sensing signal line (trace line) electrically connected to the sensing electrode, and at least one insulating layer. The input sensing layer 400 may sense an external input, for example, by a capacitive method. As described above, the operation method of the input sensing layer 400 is not particularly limited, and in some embodiments, the input sensing layer 400 may sense an external input by an electromagnetic induction method or a pressure sensing method.

The input sensing layer 400 may include a first insulating layer 410, a first touch conductive layer MTL1, an organic insulating layer 420, and a second touch conductive layer MTL2.

The first insulating layer 410 may be directly located on the encapsulation layer 300. The first insulating layer 410 may include an inorganic material or an organic material and may be provided as a single layer or multiple layers. The organic material may include at least one of acryl-based resin, methacryl-based resin, polyisoprene, vinyl-based resin, epoxy-based resin, urethane-based resin, cellulose-based resin, and perylene-based resin. The inorganic material may include at least one of silicon nitride (SiNₓ), aluminum nitride (AlN), zirconium nitride (ZrN), titanium nitride (TiN), hafnium nitride (HfN), tantalum nitride (TaN), silicon oxide (SiOₓ), aluminum oxide (Al₂O₃), titanium oxide (TiO₂), tin oxide (SnO₂), cerium oxide (CeO₂), and silicon oxynitride (SiON).

The first insulating layer 410 may prevent damage to the encapsulation layer 300 and may block an interference signal that may occur in case that the input sensing layer 400 is driven.

For example, each of the first touch conductive layer MTL1 and the second touch conductive layer MTL2 may have a single-layer structure or may have a stacked multilayer structure. The single-layer conductive layer may include a metal layer or a transparent conductive layer. The metal layer may include molybdenum (Mo), silver (Ag), titanium (Ti), copper (Cu), aluminum (Al), or any alloy thereof. The transparent conductive layer may include a transparent conductive oxide such as indium tin oxide (ITO), indium zinc oxide (IZO), zinc oxide (ZnO), or indium tin zinc oxide (ITZO). The transparent conductive layer may include a conductive polymer such as PEDOT, metal nanowire, graphene, or the like.

The multilayer conductive layer may include multilayer metal layers. The multilayer metal layers may have, for example, a three-layer structure of Ti/Al/Ti. The multilayer conductive layer may include at least one metal layer and at least one transparent conductive layer.

Each of the first touch conductive layer MTL1 and the second touch conductive layer MTL2 may include patterns. It may be understood that the first touch conductive layer MTL1 includes first conductive patterns and the second touch conductive layer MTL2 includes second conductive patterns. The first conductive patterns and the second conductive patterns may form the sensing electrode.

The first touch conductive layer MTL1 and the second touch conductive layer MTL2 may be electrically connected through a contact hole. In an embodiment, the first touch conductive layer MTL1 and the second touch conductive layer MTL2 may have a mesh structure such that the light emitted from the display element OLED may pass therethrough. The first touch conductive layer MTL1 and the second touch conductive layer MTL2 may be arranged not to overlap an emission area EA.

The organic insulating layer 420 may include an organic material. The organic material may include at least one of acryl-based resin, methacryl-based resin, polyisoprene, vinyl-based resin, epoxy-based resin, urethane-based resin, cellulose-based resin, and perylene-based resin. The organic insulating layer 420 may further include an inorganic material. The inorganic material may include at least one of silicon nitride (SiNₓ), aluminum nitride (AlN), zirconium nitride (ZrN), titanium nitride (TiN), hafnium nitride (HfN), tantalum nitride (TaN), silicon oxide (SiOₓ), aluminum oxide (Al₂O₃), titanium oxide (TiO₂), tin oxide (SnO₂), cerium oxide (CeO₂), and silicon oxynitride (SiON). In the display area DA, a thickness T_{DA} of the organic insulating layer 420 may be about 0.7 μm or more. In some embodiments, the thickness T_{DA} of the organic insulating layer 420 may be about 0.7 μm to about 2 μm.

A second insulating layer 430 may be disposed on the second touch conductive layer MTL2. The second insulating layer 430 may have a single-layer or multilayer structure. The second insulating layer 430 may include an organic material, an inorganic material, or a compound material thereof. The inorganic material may include at least one of silicon nitride (SiNₓ), aluminum nitride (AlN), zirconium nitride (ZrN), titanium nitride (TiN), hafnium nitride (HfN), tantalum nitride (TaN), silicon oxide (SiOₓ), aluminum oxide (Al₂O₃), titanium oxide (TiO₂), tin oxide (SnO₂), cerium oxide (CeO₂), and silicon oxynitride (SiON). The organic material may include at least one of acryl-based resin, methacryl-based resin, polyisoprene, vinyl-based resin, epoxy-based resin, urethane-based resin, cellulose-based resin, and perylene-based resin.

An optical function layer or the like for improving the light extraction efficiency of the display element OLED may be further disposed on the input sensing layer 400.

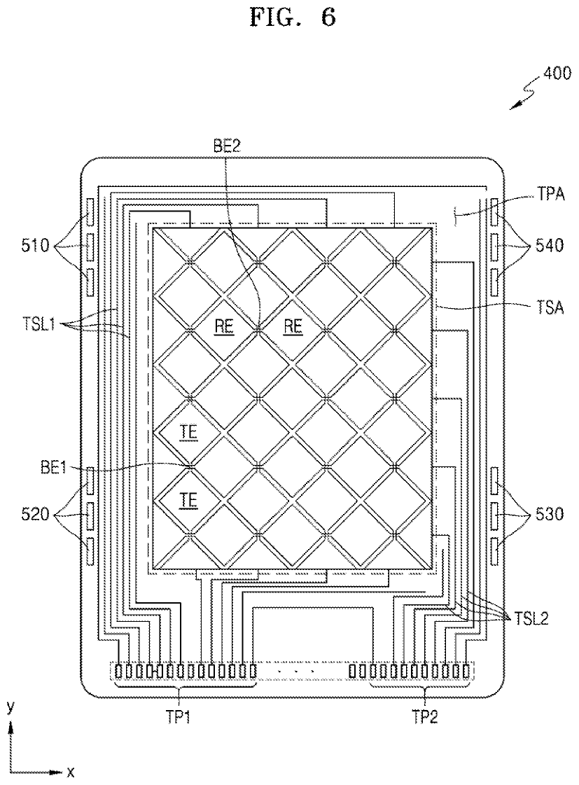

FIG. 6 is a plan view schematically illustrating a portion of a display apparatus according to an embodiment. FIG. 6 illustrates only a driving electrode TE, a sensing electrode RE, a first sensing signal line TSL1, a second sensing signal line TSL2, a first input sensing pad TP1, a second input sensing pad TP2, and metal patterns 510, 520, 530, and 540 included in a first touch conductive layer MTL1 and a second touch conductive layer MTL2 of an input sensing layer 400.

Referring to FIG. 6, the input sensing layer 400 may include a touch sensing area TSA for sensing a user's touch and a touch peripheral area TPA arranged around the touch sensing area TSA. The touch sensing area TSA may overlap a display area DA of a substrate 100, and the touch peripheral area TPA may overlap a peripheral area PA of the substrate 100.

Each of the driving electrode TE and the sensing electrode RE may have a planar diamond shape; however, the disclosure is not limited thereto. For convenience of illustration, FIG. 6 illustrates that it has a planar diamond shape; however, the driving electrode TE, the sensing electrode RE, a first touch connection electrode BE1, and a second touch connection electrode BE2 may be formed in a mesh structure or a mesh structure in a plan view. Sensing electrodes RE may be arranged in a first direction (e.g., the x direction) and may be electrically connected to each other. Driving electrodes TE may be arranged in a second direction (e.g., the y direction) intersecting the first direction (e.g., the x direction) and may be electrically connected to each other. The driving electrodes TE and the sensing electrodes RE may be arranged apart from each other. The driving electrodes TE may be arranged in parallel in the second direction (e.g., the y direction). In the intersection areas between the sensing electrodes RE and the driving electrodes TE, the driving electrodes TE adjacent to each other in the second direction (e.g., the y direction) may be electrically connected through the first touch connection electrode BE1, and the sensing electrodes RE adjacent to each other in the first direction (e.g., the x direction) may be electrically connected through the second touch connection electrode BE2.

The first sensing signal line TSL1 and the second sensing signal line TSL2 may be arranged in the touch peripheral area TPA. The driving electrodes TE of the touch sensing area TSA may be electrically connected to the first sensing signal lines TSL1. The first sensing signal lines TSL1 may be electrically connected to the first input sensing pads TP1.

Among the sensing electrodes RE, a sensing electrode arranged at one end thereof may be electrically connected to the second sensing signal line TSL2 to be electrically connected to the second input sensing pads TP2.

Some of the first sensing signal lines TSL1 and the second sensing signal lines TSL2 may be ground lines not electrically connected to the driving electrode TE and the sensing electrode RE.

The metal patterns 510, 520, 530, and 540 may be arranged outside the first sensing signal lines TSL1 and the second sensing signal lines TSL2. The metal patterns 510, 520, 530, and 540 may include a metal island spaced apart from the first sensing signal lines TSL1 and the second sensing signal lines TSL2 and may be electrically insulated from other components.

FIG. 6 illustrates that a first metal pattern 510 and a fourth metal pattern 540 are arranged to face each other on the upper side of the touch peripheral area TPA with the touch sensing area TSA therebetween and a second metal pattern 520 and a third metal pattern 530 are arranged to face each other on the lower side of the touch peripheral area TPA with the touch sensing area TSA therebetween; however, the disclosure is not limited thereto. As described above, the metal patterns 510, 520, 530, and 540 may be added or some of them may be omitted.

In an embodiment, the driving electrode TE, the sensing electrode RE, the second touch connection electrode BE2, and the metal patterns 510, 520, 530, and 540 may be provided as the second touch conductive layer MTL2 (see FIG. 5), and the first touch connection electrode BE1 may be provided as the first touch conductive layer MTL1 (see FIG. 5). For example, the metal patterns 510, 520, 530, and 540, the driving electrode TE, the sensing electrode RE, and the second touch connection electrode BE2 may include a same material. Herein, that “A and B include a same material” may imply that “A and B are formed together by a same process”.

In another embodiment, the driving electrode TE, the sensing electrode RE, and the second touch connection electrode BE2 may be provided as the first touch conductive layer MTL1 (see FIG. 5), and the first touch connection electrode BE1 and the metal patterns 510, 520, 530, and 540 may be provided as the second touch conductive layer MTL2 (see FIG. 5). For example, the metal patterns 510, 520, 530, and 540 and the first touch connection electrode BE1 may include a same material.

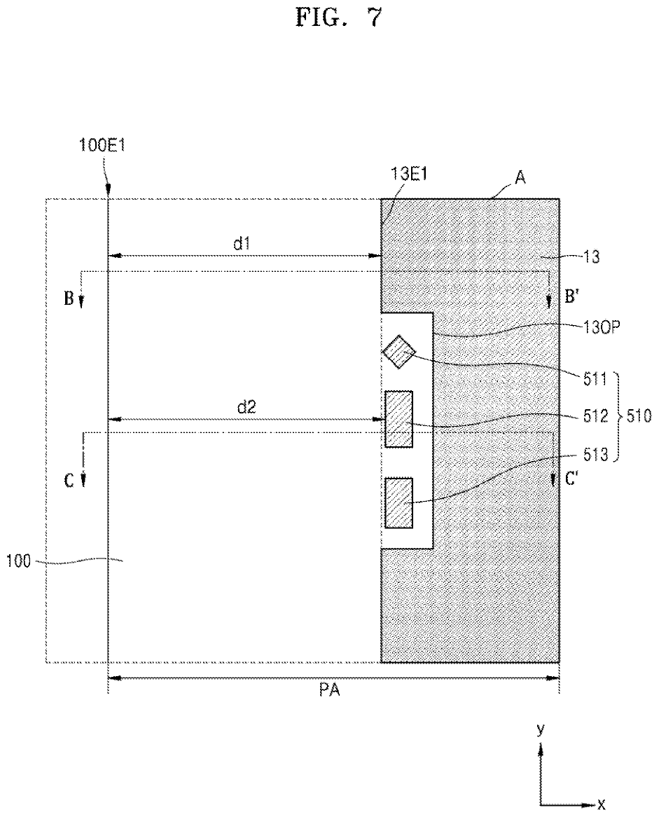

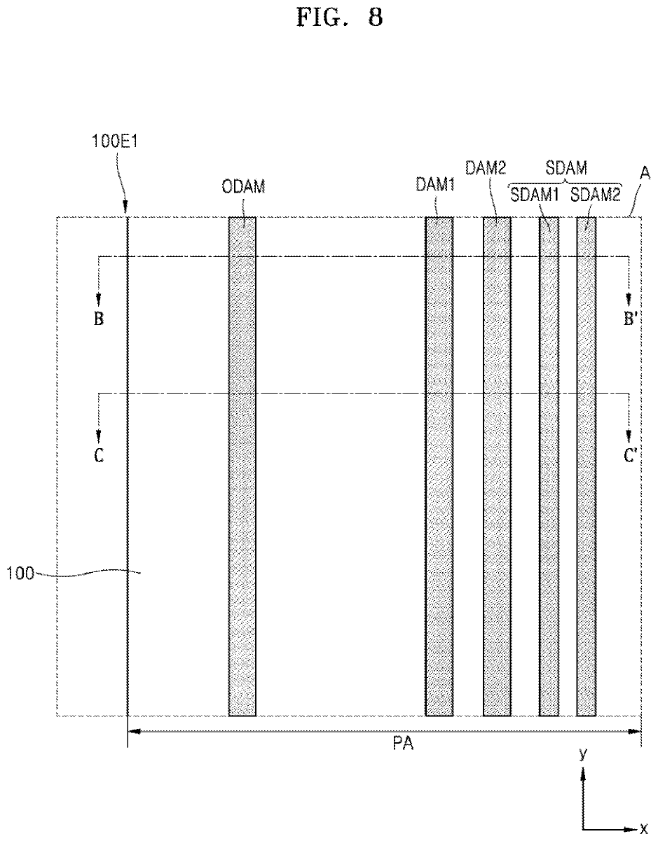

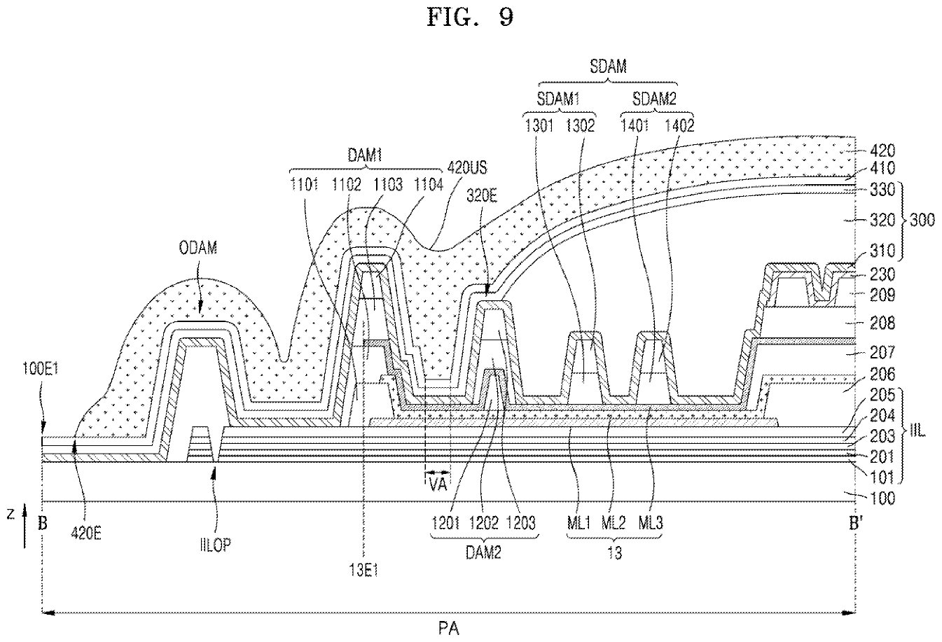

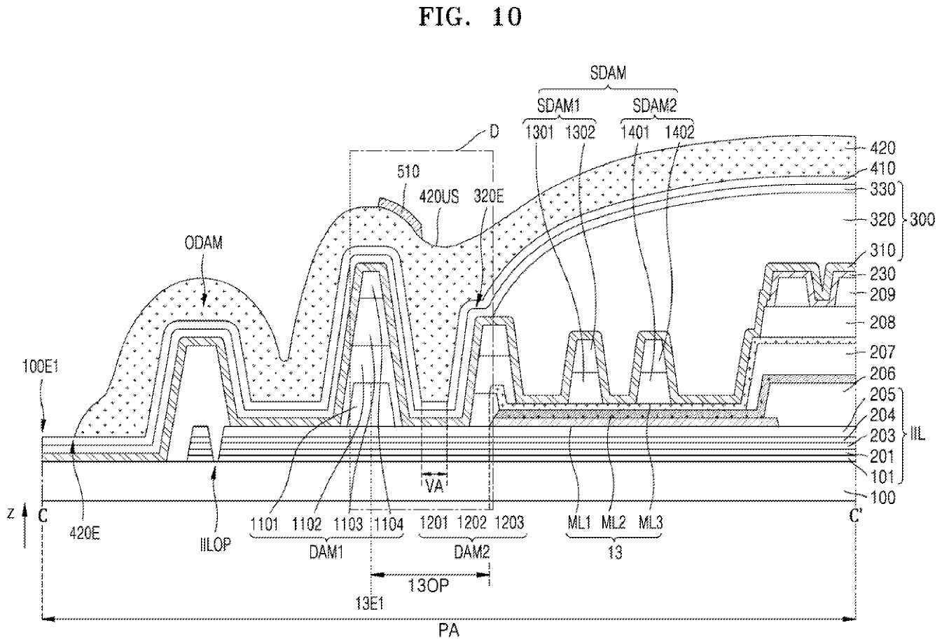

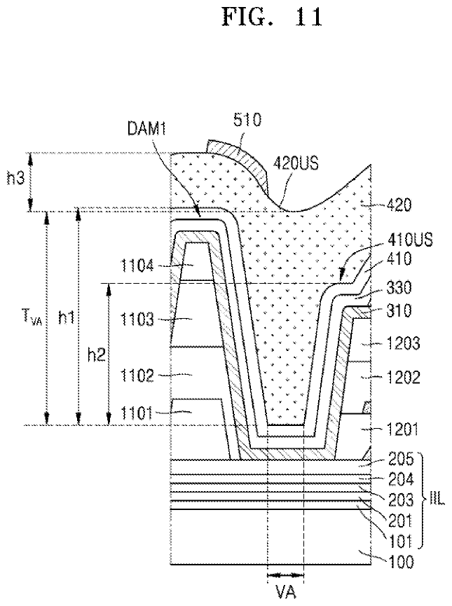

FIGS. 7 and 8 are schematic enlarged plan views of region A of FIG. 1. FIG. 9 is a schematic cross-sectional view of region A taken along line B-B′ of FIG. 7, FIG. 10 is a schematic cross-sectional view of region A taken along line C-C′ of FIG. 7, and FIG. 11 is a schematic enlarged view of region D of FIG. 10. In order to describe the arrangement of the common voltage supply line 13 and the first metal pattern 510, FIG. 7 illustrates only the common voltage supply line 13 and the first metal pattern 510, and FIG. 8 illustrates a first dam DAM1, a second dam DAM2, subdams SDAM, and an outer dam ODAM arranged in region A.

Referring to FIGS. 7, 8, and 9, the common voltage supply line 13 may be arranged parallel to the first boundary 100E1 of the substrate 100. For example, in case that the first boundary 100E1 of the substrate 100 is parallel to the second direction (e.g., the y direction), the common voltage supply line 13 may extend in the second direction (e.g., the y direction).

The common voltage supply line 13 may include at least one conductive line. For example, the common voltage supply line 13 may include a first conductive line ML1, a second conductive line ML2, and a third conductive line ML3. The first conductive line ML1 may be disposed on the interlayer insulating layer 205. The first conductive line ML1 and the source electrode SE and the drain electrode DE of the thin film transistor TFT (see FIG. 5) may include a same material. A portion of the second conductive line ML2 may be disposed on the first planarization insulating layer 206 extending from the display area DA (see FIG. 5) to a portion of the peripheral area PA. The second conductive line ML2 and the first connection electrode CM1 may include a same material. A portion of the third conductive line ML3 may be disposed on the second planarization insulating layer 207 extending from the display area DA (see FIG. 5) to a portion of the peripheral area PA. The third conductive line ML3 and the second connection electrode CM2 may include a same material.

The first conductive line ML1, the second conductive line ML2, and the third conductive line ML3 may be arranged overlapping each other and may have a loop shape with an open side to surround at least a portion of the display area DA (see FIG. 4).

The second conductive line ML2 may further extend from the end of the first planarization insulating layer 206 in the direction of the first boundary 100E1 of the substrate 100 to contact the first conductive line ML1. Likewise, the third conductive line ML3 may further extend from the end of the second planarization insulating layer 207 in the direction of the first boundary 100E1 of the substrate 100 to contact the second conductive line ML2. The common voltage supply line 13 may have a low resistance by including the first conductive line ML1, the second conductive line ML2, and the third conductive line ML3 disposed on different layers.

In some embodiments, some of the first conductive line ML1, the second conductive line ML2, and the third conductive line ML3 may be omitted. The common voltage supply line 13 may further include a conductive line located on a different layer than the first conductive line ML1, the second conductive line ML2, and the third conductive line ML3.

The first dam DAM1 may be arranged overlapping an outer boundary 13E1 of the common voltage supply line 13. Herein, the ‘outer boundary’ may refer to a boundary adjacent to the first boundary 100E1, the second boundary 100E2, and the third boundary 100E3 of the substrate 100, and the ‘inner boundary’ may refer to a boundary adjacent to the display area DA (see FIG. 1). The first dam DAM1 may include a (1-1)th organic layer 1101, a (1-2)th organic layer 1102, a (1-3)th organic layer 1103, and a (1-4)th organic layer 1104. The (1-1)th organic layer 1101 may be arranged to cover the boundary of the first conductive line ML1. The second conductive line ML2 may be disposed on the (1-1)th organic layer 1101, and the (1-2)th organic layer 1102 may be arranged to cover the boundary of the second conductive line ML2. The third conductive line ML3 may be disposed on the (1-2)th organic layer 1102, and the (1-3)th organic layer 1103 may be arranged to cover the boundary of the third conductive line ML3. The (1-4)th organic layer 1104 may be disposed on the (1-3)th organic layer 1103.

In an embodiment, the (1-1)th organic layer 1101 of the first dam DAM1 and the first planarization insulating layer 206 may include a same material, the (1-2)th organic layer 1102 and the second planarization insulating layer 207 may include a same material, the (1-3)th organic layer 1103 and the third planarization insulating layer 208 may include a same material, and the (1-4)th organic layer 1104 and the pixel definition layer 209 may include a same material. In some embodiments, the first dam DAM1 may further include other organic layers, or some of the above layers may be omitted.

The second dam DAM2 may be arranged apart from the first dam DAM1 in the direction of the display area DA (see FIG. 4). The second dam DAM2 may be arranged overlapping the common voltage supply line 13. The second dam DAM2 may include a (2-1)th organic layer 1201, a (2-2)th organic layer 1202, and a (2-3)th organic layer 1203. In an embodiment, the (2-1)th organic layer 1201 and the second planarization insulating layer 207 may include a same material, the (2-2)th organic layer 1202 and the third planarization insulating layer 208 may include a same material, and the (2-3)th organic layer 1203 and the pixel definition layer 209 may include a same material. In some embodiments, the second dam DAM2 may further include other organic layers, or some of the above layers may be omitted.

The subdams SDAM may be arranged apart from the second dam DAM2 in the direction of the display area DA (see FIG. 1). The subdams SDAM may include a first subdam SDAM1 and a second subdam SDAM2. The first subdam SDAM1 may include a (3-1)th organic layer 1301 and a (3-2)th organic layer 1302, and the second subdam SDAM2 may include a (4-1)th organic layer 1303 and a (4-2)th organic layer 1304. The (3-1)th organic layer 1301, the (4-1)th organic layer 1303, and the third planarization insulating layer 208 may include a same material. The (3-2)th organic layer 1302, the (4-2)th organic layer 1304, and the pixel definition layer 209 may include a same material. The subdams SDAM may further include other organic layers, or some of the above layers may be omitted.

The second dam DAM2 and the subdams SDAM may prevent the organic encapsulation layer 320 from overflowing toward the first boundary 100E1 of the substrate 100. For example, an end 320E of the organic encapsulation layer 320 may be disposed over the upper surface of the second dam DAM2 or may contact the inner surface of the second dam DAM2 facing the display area DA (see FIG. 4).

A valley area VA may be provided between the first dam DAM1 and the second dam DAM2. In the valley area VA between the first dam DAM1 and the second dam DAM2, the first inorganic encapsulation layer 310 and the second inorganic encapsulation layer 330 may directly contact each other to form an inorganic contact area.

A dam part including the first dam DAM1, the second dam DAM2, and the subdams SDAM may surround at least a portion of the display area DA (see FIG. 5).

An outer dam ODAM may be arranged adjacent to the first boundary 100E1 of the substrate 100. The outer dam ODAM may prevent or reduce the propagation of a crack generated from the first boundary 100E1 of the substrate 100 to the display area DA (see FIG. 1) by the inorganic insulating layer. The outer dam ODAM may include an organic material and may cover the ends of inorganic insulating layers IIL extending to the peripheral area PA.

In some embodiments, at least a portion of the inorganic insulating layers IIL may be removed such that a hole IILOP exposing a portion of the buffer layer 201, the barrier layer 101, or the upper surface of the substrate 100 may be arranged overlapping the outer dam ODAM. In an embodiment, the inorganic insulating layer IIL may include a barrier layer 101, a buffer layer 201, a first gate insulating layer 203, a second gate insulating layer 204, and an interlayer insulating layer 205, and the hole IILOP may be an overlap between an opening of the barrier layer 101, an opening of the buffer layer 201, an opening of the first gate insulating layer 203, an opening of the second gate insulating layer 204, and an opening of the interlayer insulating layer 205. The openings may be separately formed through separate processes or may be simultaneously formed through a same process. As another example, the inorganic insulating layer IIL may include a groove rather than the hole IILOP exposing a portion of the upper surface of the substrate 100. As another example, the inorganic insulating layer IIL may not include a hole or a groove overlapping the outer dam ODAM.

The organic insulating layer 420 may extend from the display area DA (see FIG. 5) toward the first boundary 100E1 of the substrate 100. The outer dam ODAM may prevent the organic insulating layer 420 from overflowing toward the first boundary 100E1 of the substrate 100. FIG. 9 illustrates that an end 420E of the organic insulating layer 420 is located between the outer dam ODAM and the first boundary 100E1 of the substrate 100. In some embodiments, the end 420E of the organic insulating layer 420 may be located over the upper surface of the outer dam ODAM, may contact the inner surface of the outer dam ODAM facing the display area DA (see FIG. 5), or may be located between the outer dam ODAM and the first dam DAM1.

The organic insulating layer 420 may fill the valley area VA located between the first dam DAM1 and the second dam DAM2 such that an upper surface 420US of the organic insulating layer 420 410 may have a gentler slope than an upper surface 410US of the first insulating layer 410.

The first metal pattern 510 may be disposed on the organic insulating layer 420. The first metal pattern 510 and the common voltage supply line 13 may be disposed on different layers to be sufficiently insulated from the common voltage supply line 13.

As illustrated in FIG. 9, in a view in a direction substantially perpendicular to the substrate 100, the first metal pattern 510 may be arranged apart from the common voltage supply line 13. For example, the common voltage supply line 13 may include an opening portion 130P from which a portion of the common voltage supply line 13 is removed not to overlap the first metal pattern 510. In some embodiments, the common voltage supply line 13 may include a first conductive line ML1, a second conductive line ML2, and a third conductive line ML3, and the opening portion 130P of the common voltage supply line 13 may be an overlap between an opening of the first conductive line ML1, an opening of the second conductive line ML2, and an opening of the third conductive line ML3. In an area where the opening portion 130P of the common voltage supply line 13 is arranged, except for the first metal pattern 510, a component including a metal material may not be arranged. The opening portion 130P of the common voltage supply line 13 may function as an alignment mark detection area. As illustrated in FIG. 1, the common voltage supply line 13 may include one or more opening portions not to overlap the metal patterns 510, 520, 530, and 540 (see FIG. 1).

In some embodiments, the opening portion 130P of the common voltage supply line 13 may have a rectangular shape surrounding the first metal pattern 510 in a view in a direction substantially perpendicular to the substrate 100; however, the disclosure is not limited thereto. In some other embodiments, the opening portion 130P of the common voltage supply line 13 may have various shapes such as circular shapes or polygonal shapes.

In some embodiments, the opening portion 130P of the common voltage supply line 13 may have a concave shape with an open side by contacting the extension line of the outer boundary 13E1 of the common voltage supply line 13. The first metal pattern 510 may be arranged adjacent to the extension line of the outer boundary 13E1 of the common voltage supply line 13 to minimize the area reduction of the common voltage supply line 13 due to the opening portion 130P of the common voltage supply line 13. In some other embodiments, the opening portion 130P of the common voltage supply line 13 may be spaced apart from the outer boundary 13E1 of the common voltage supply line 13 to have a closed figure shape.

The first metal pattern 510 may include metal islands. For example, FIG. 7 illustrates that the first metal pattern 510 includes a first island 511, a second island 512, and a third island 513; however, the disclosure is not limited thereto. In some embodiments, the first metal pattern 510 may include a greater number of metal islands or may include a smaller number of metal islands.

The first island 511, the second island 512, or the third island 513 may have various shapes such as circular shapes, polygonal shapes, or cross shapes in a view in a direction substantially perpendicular to the substrate 100. The first island 511, the second island 512, or the third island 513 may have a same shape or may have different shapes.

The first island 511, the second island 512, and the third island 513 may function as an alignment mark, or each may function as an alignment mark. Herein, in a process of joining the display panel 10 (see FIG. 2) and the cover window CW (or the functional module 20) (see FIG. 2) together, an alignment mark (or alignment key) may be used as an identification mark for detecting the position of the display panel 10 (see FIG. 2) or aligning the display panel 10 (see FIG. 2).

A laser cutting process for separating the display panel 10 (see FIG. 2) from a mother substrate may be performed along the first boundary 100E1 of the substrate 100. In order to prevent the first metal pattern 510 from being damaged due to the heat generated by the laser cutting process, the first metal pattern 510 may be arranged apart from the first boundary 100E1 of the substrate 100 by a second distance d2. As the area of the peripheral area PA decreases, in order for the second distance d2 to have a sufficient size, the first metal pattern 510 may be arranged to be closer to the display area DA (see FIG. 1) than the extension line of the outer boundary 13E1 of the common voltage supply line 13, or the first metal pattern 510 and the extension line of the outer boundary 13E1 of the common voltage supply line 13 may be arranged to have a same distance to the display area DA (see FIG. 1). For example, the second distance d2 between the first metal pattern 510 and the first boundary 100E1 of the substrate 100 may be greater than or equal to a first distance d1 between the common voltage supply line 13 and the first boundary 100E1 of the substrate 100.

As the first metal pattern 510 is arranged closer to the display area DA (see FIG. 1) than the outer boundary 13E1 of the common voltage supply line 13, the first metal pattern 510 may overlap the first dam DAM1 or may overlap the valley area VA between the first dam DAM1 and the second dam DAM2. As described above, the end 320E of the organic encapsulation layer 320 may be disposed over the upper surface of the second dam DAM2 or may contact the inner surface of the second dam DAM2.

Referring to FIG. 11, the upper surface 410US of the first insulating layer 410 overlapping the upper surface of the first dam DAM1 may have a step height equal to a first height h1 with respect to the upper surface 410US of the first insulating layer 410 overlapping the valley area VA, and the upper surface 410US of the first insulating layer 410 overlapping the upper surface of the second dam DAM2 may have a step height equal to a second height h2 with respect to the upper surface 410US of the first insulating layer 410 overlapping the valley area VA. As a comparative example, in case that the first metal pattern is disposed on the upper surface of the first insulating layer, a residual metal layer that is not removed after the first metal pattern is formed may remain in the valley area. Due to the residual metal layer, the shadow shape of the first metal pattern may be deformed, and thus, the recognition rate of the alignment mark may be degraded.

Thus, in embodiments, the organic insulating layer 420 may extend toward the first boundary 100E1 of the substrate 100 and fill at least a portion of the valley area VA to include a relatively flat upper surface 420US in an area where the first metal pattern 510 is formed. The upper surface 420US of the organic insulating layer 420 overlapping the upper surface of the first dam DAM1 may have a step height equal to a third height h3 with respect to the upper surface 420US of the organic insulating layer 420 overlapping the valley area VA. The third height h3 may be smaller than the first height h1 and the second height h2.

In some embodiments, the third height h3 may be about 3 μm or less. In some embodiments, a thickness TVA of the organic insulating layer 420 in the valley area VA may be about 1.4 μm or more. In some embodiments, the thickness TVA of the organic insulating layer 420 in the valley area VA may be about 1.4 μm to about 4 μm. Thus, the upper surface 420US of the organic insulating layer 420 may have a gentler slope than the upper surface 410US of the first insulating layer 410. In order to minimize the area loss of the common voltage supply line 13, the opening portion 130P of the common voltage supply line 13 may be arranged overlapping the valley area VA to contact the outer boundary 13E1 of the common voltage supply line 13. In a view in a direction substantially perpendicular to the substrate 100, the first metal pattern 510 may be arranged apart from the common voltage supply line 13 in order not to overlap the common voltage supply line 13. As described above, the first metal pattern 510 may be disposed on the upper surface 420US of the organic insulating layer 420. The upper surface 420US of the organic insulating layer 420 may have a gentle slope in the valley area VA to prevent or reduce the remaining of the residual metal layer in the valley area VA in the patterning process of the first metal pattern 510.

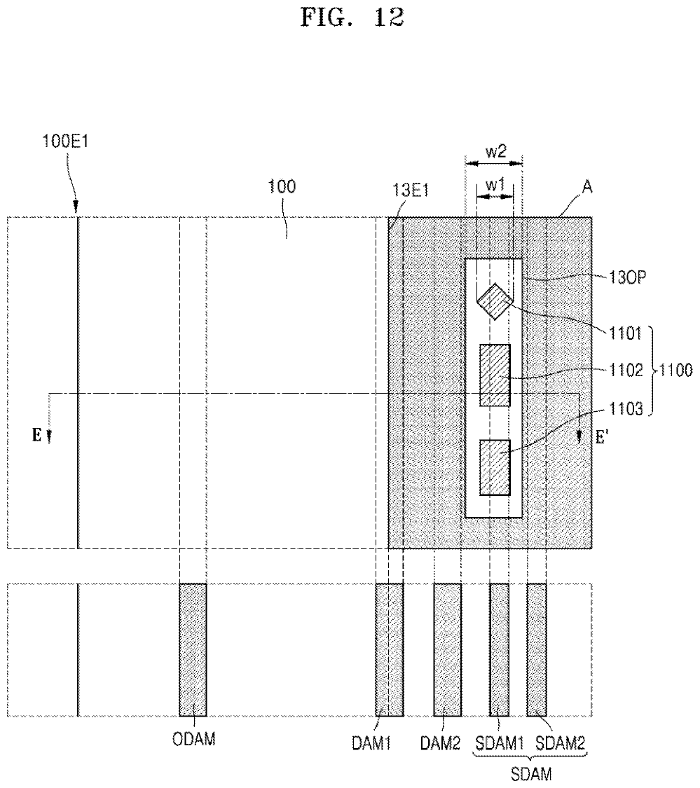

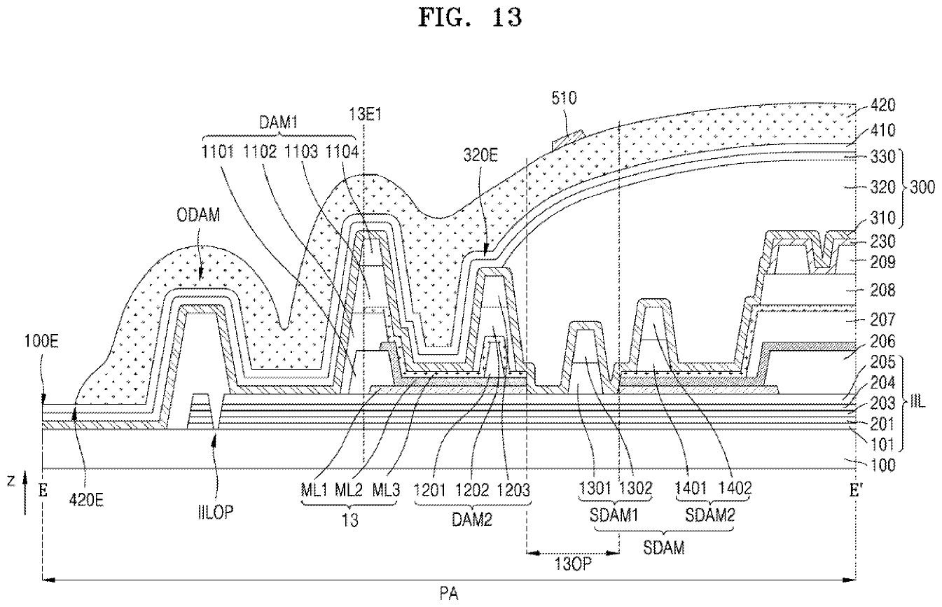

FIG. 12 is a schematic plan view illustrating a modification of FIG. 7, and FIG. 13 is a schematic cross-sectional view of the modification taken along line E-E′ of FIG. 12.

Referring to FIGS. 12 and 13, the first metal pattern 510 may be located inside the second dam DAM2. As described above, the end 320E of the organic encapsulation layer 320 may be disposed over the upper surface of the second dam DAM2 or may contact the inner surface of the second dam DAM2. Thus, the inside of the second dam DAM2 may include a flatter upper surface due to the organic encapsulation layer 320.

The second inorganic encapsulation layer 330, the first insulating layer 410, and the organic insulating layer 420 may be sequentially disposed on the organic encapsulation layer 320, and the first metal pattern 510 may be disposed on the upper surface of the organic insulating layer 420. The first metal pattern 510 may be arranged overlapping the organic encapsulation layer 320 in a view in a direction substantially perpendicular to the substrate 100. The first metal pattern 510 may be disposed on the upper surface of the organic insulating layer 420 that is more planarized by the organic encapsulation layer 320, thereby preventing or reducing the remaining of the residual metal layer in the patterning process of the first metal pattern 510.

Metal islands constituting the first metal pattern 510 may be electrically insulated from peripheral components. In order to prevent the first metal pattern 510 from acting as an inflow path of static electricity of adjacent components, the first metal pattern 510 may be spaced apart from the adjacent components by a sufficient distance. For example, the first metal pattern 510 may be arranged between the second dam DAM2 and the second subdam SDAM2 to be sufficiently spaced apart from the outermost line of the first sensing signal line TSL1 (see FIG. 6) and the second sensing signal line TSL2 (see FIG. 6). Here, the second subdam SDAM2 may be a dam arranged closest to the display area DA (see FIG. 5) among the subdams SDAM.

In a view in a direction substantially perpendicular to the substrate 100, the first metal pattern 510 may be arranged in the opening portion 130P of the common voltage supply line 13. The opening portion 130P of the common voltage supply line 13 may overlap the organic encapsulation layer 320. For example, the opening portion 130P of the common voltage supply line 13 may be arranged between the second dam DAM2 and the second subdam SDAM2. The opening portion 130P may have a closed figure shape. A width w2 of the opening portion 130P of the common voltage supply line 13 in the first direction (e.g., the x direction) may be greater than a width w1 of the first metal pattern 510 such that the common voltage supply line 13 and the first metal pattern 510 may not overlap each other.

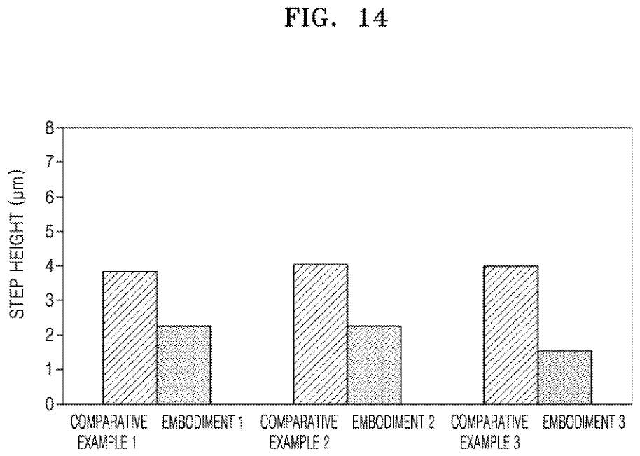

FIG. 14 is a graph illustrating the step height in an area between a first dam and a second dam of each of display apparatuses according to embodiments and display apparatuses according to comparative examples.

The display apparatuses according to comparative examples may include, on a first insulating layer, a touch insulating layer including an inorganic material and extending to the boundary of a substrate. The touch insulating layer may be a layer arranged between a first touch conductive layer and a second touch conductive layer of an input sensing layer in a display area. The step height in an area between a first dam and a second dam of the display apparatuses according to comparative examples was calculated by measuring the heights of the upper surface of the touch insulating layer in an area overlapping the upper surface of the first dam and a valley area respectively.

The display apparatuses according to an embodiment and the display apparatuses according to corresponding comparative examples may have a substantially same stack structure up to the first insulating layer, and the display apparatuses according to an embodiment may be different from the display apparatuses according to corresponding comparative examples at least in that the display apparatuses according to an embodiment include an organic insulating layer on the first insulating layer. The step height in an area between a first dam and a second dam of the display apparatuses according to an embodiment was calculated by measuring the heights of the upper surface of the organic insulating layer in an area overlapping the upper surface of the first dam and a valley area respectively. In the area between the first dam and the second dam of Comparative Example 1, the step height of the touch insulating layer may be about 3.84 μm. In Embodiment 1, the application thickness of an organic material forming the organic insulating layer may be about 1.9 μm, and the step height of the organic insulating layer in the area between the first dam and the second dam may be about 2.26 μm.

In the area between the first dam and the second dam of Comparative Example 2, the step height of the touch insulating layer may be about 4.06 μm. In Embodiment 2, the application thickness of an organic material forming the organic insulating layer may be about 2.9 μm, and the step height of the organic insulating layer in the area between the first dam and the second dam may be about 2.28 μm.

In the area between the first dam and the second dam of Comparative Example 3, the step height of the touch insulating layer may be about 4.02 μm. In Embodiment 3, the application thickness of an organic material forming the organic insulating layer may be about 3.6 μm, and the step height of the organic insulating layer in the area between the first dam and the second dam may be about 1.54 μm.

As described above, because the residual metal layer may remain in the valley area in case that the step height of the organic insulating layer exceeds about 3 μm, the step height of the organic insulating layer may be about 3 μm or less in some embodiments.

In case that the application thickness of the organic material is about 1.5 μm, the step height of the organic insulating layer may be about 3 μm, the thickness T_{DA} (see FIG. 5) of the organic insulating layer in the display area DA (see FIG. 5) may be about 0.7 μm, and the thickness TVA (see FIG. 11) of the organic insulating layer in the valley area VA (see FIG. 11) may be about 1.4 μm. Thus, the thickness T_{DA} (see FIG. 5) of the organic insulating layer in the display area DA (see FIG. 5) may be about 0.7 μm to about 2 μm, and the thickness TVA (see FIG. 11) of the organic insulating layer in the valley area VA (see FIG. 11) may be about 1.4 μm to about 4 μm.

According to an embodiment described above, a display apparatus including an extended display area because the area of a dead space is reduced may be implemented. However, the scope of the disclosure is not limited to these effects.

The above description is an example of technical features of the disclosure, and those skilled in the art to which the disclosure pertains will be able to make various modifications and variations. Thus, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display apparatus comprising:
a display area in which a display element is arranged and a peripheral area adjacent to the display area;
a dam part disposed on a substrate in the peripheral area to surround the display area;
an encapsulation layer disposed on the substrate in the display area and the peripheral area to encapsulate the display element;
an organic insulating layer disposed on the encapsulation layer and extending from the display area to the peripheral area to cover the dam part; and
a metal pattern disposed on the organic insulating layer and overlapping the dam part in a plan view.

2. The display apparatus of claim 1, wherein
the dam part includes:
a first dam; and
a second dam spaced apart from the first dam in a direction of the display area, and
the organic insulating layer fills at least a portion of a valley area between the first dam and the second dam.

3. The display apparatus of claim 2, wherein the metal pattern overlaps the first dam or the valley area between the first dam and the second dam in a plan view.

4. The display apparatus of claim 2, wherein
the dam part includes at least one subdam spaced apart from the second dam in a direction,
the encapsulation layer includes at least one inorganic encapsulation layer and at least one organic encapsulation layer,
the at least one organic encapsulation layer extends from the display area to the second dam, and
the metal pattern overlaps the at least one organic encapsulation layer in a plan view.

5. The display apparatus of claim 2, wherein
a thickness of the organic insulating layer in the display area is about 0.7 μm or more, and
a thickness of the organic insulating layer in the valley area is about 1.4 μm or more.

6. The display apparatus of claim 1, further comprising:
at least one inorganic insulating layer disposed on the substrate in the display area and the peripheral area; and
an outer dam disposed on the substrate in the peripheral area and covering an end of the at least one inorganic insulating layer.

7. The display apparatus of claim 6, wherein the at least one inorganic insulating layer includes a hole or a groove overlapping the outer dam in a plan view.

8. The display apparatus of claim 1, further comprising:
a common voltage supply line disposed on the substrate in the peripheral area,
wherein the metal pattern and the common voltage supply line are spaced apart from each other in a plan view.

9. The display apparatus of claim 8, wherein the common voltage supply line includes a plurality of conductive lines disposed on different layers.

10. The display apparatus of claim 9, further comprising:
a pixel circuit arranged in the display area and including:
a thin film transistor; and
a storage capacitor,
wherein at least one of the plurality of conductive lines and a source electrode or a drain electrode of the thin film transistor include a same material.

11. The display apparatus of claim 9, further comprising:
a pixel circuit arranged in the display area and including:
a thin film transistor; and
a storage capacitor; and
a connection electrode electrically connecting a source electrode or a drain electrode of the thin film transistor to a pixel electrode of the display element,
wherein at least one of the plurality of conductive lines and the connection electrode include a same material.

12. The display apparatus of claim 8, wherein
the common voltage supply line includes an opening portion, and
the metal pattern is located inside the opening portion.

13. The display apparatus of claim 12, wherein the opening portion includes a plurality of opening portions.

14. The display apparatus of claim 12, wherein the opening portion contacts an outer boundary of the common voltage supply line.

15. The display apparatus of claim 12, wherein a width of the opening portion in a first direction is greater than a width of the metal pattern in the first direction.

16. The display apparatus of claim 8, wherein
the dam part includes:
a first dam; and
a second dam spaced apart from the first dam in a direction, and
the first dam covers an outer boundary of the common voltage supply line.

17. The display apparatus of claim 16, wherein
the common voltage supply line includes an opening portion overlapping a valley area between the first dam and the second dam in a plan view, and
the metal pattern is located inside the opening portion.

18. The display apparatus of claim 1, further comprising:
a first touch conductive layer disposed on the encapsulation layer; and
a second touch conductive layer disposed on the first touch conductive layer,
wherein the organic insulating layer is located between the first touch conductive layer and the second touch conductive layer.

19. The display apparatus of claim 18, wherein the metal pattern and the second touch conductive layer include a same material.

20. The display apparatus of claim 18, wherein
the second touch conductive layer includes an input signal line overlapping the peripheral area in a plan view, and
the metal pattern is spaced apart from the input signal line.
